(19) United States
(12) Patent Application Publication
(10) Pub. No.: US 2014/0150854 A1
(43) Pub. Date: Jun. 5, 2014

(54) Patterned Transparent Photovoltaic Backsheet

(71) Applicant: Saint-Gobain Performance Plastics Corporation, Aurora, OH (US)

(72) Inventor: Yongzhong Wang, Tucson, AZ (US)

(73) Assignee: Saint-Gobain Performance Plastics Corporation, Aurora, OH (US)

(21) Appl. No.: 14/096,806

(22) Filed: Dec. 4, 2013

Related U.S. Application Data
(60) Provisional application No. 61/732,932, filed on Dec. 4, 2012.

(51) Int. Cl. H01L 31/048

(52) U.S. Cl. CPC H01L 31/0487
USPC 136/252

(57) ABSTRACT

A multilayer photovoltaic backsheet comprising a transparent substrate with same polymeric coatings on both sides of the substrate or a different polymeric coating on either side of the substrate. The use of coatings instead of laminated layers provides for a manufacturing process that is faster, has fewer steps, and is more cost effective. Coatings can be tailored to provide excellent adhesion, without the problems of delamination seen in prior art laminated backsheets. The coating for the outer side of the substrate can also be tailored to be softened during module lamination. A patterned blanket or other patterned or textured surface can be pressed against the outer side coating layer during lamination. The pattern or texture is thus transferred to the outer side of the backsheet, which will cause light passing through the backsheet to be diffused. Latent cross-linking reaction can further harden the outer side coating layer to increase the outer side coating layer hardness and to improve its durability.

### CROSS-REFERENCE TO RELATED APPLICATION

The present application claims priority from U.S. Provisional Patent Application No. 61/732,932, filed Dec. 4, 2012, entitled “PATTERNED TRANSPARENT PHOTOVOLTAIC BACKSHEET”, naming inventor Yongzhong Wang, which application is incorporated by reference herein in its entirety.

### FIELD OF THE DISCLOSURE

This disclosure, in general, relates to a photovoltaic backsheet, and in particular to a transparent photovoltaic backsheet with a patterned surface.

### BACKGROUND

Photovoltaic or solar cells are used to produce electrical energy from sunlight. These solar cells are built from various semiconductor systems which must be protected from environmental effects such as moisture, oxygen, and UV light. The cells are usually jacketed on both sides by encapsulating layers of glass and/or plastic films forming a multilayer structure known as a photovoltaic module. As used herein, a photovoltaic module is a module capable of converting the energy originating from a radiation, in particular solar radiation, into electrical energy, this definition including hybrid photovoltaic/thermal modules. Conventionally, a photovoltaic solar module takes the form of photovoltaic cells inserted between a transparent front substrate, designed to be placed on the side of incidence of the solar radiation on the module, and a transparent or opaque rear substrate, also called the designed to be arranged facing a structure for mounting the module

FIG. 1 shows a prior art photovoltaic module 100. As shown in FIG. 1, a photovoltaic module 100 usually has a layer of glass 102 in the front and solar cells 104 surrounded by an encapsulant layer 106, typically ethylene vinyl acetate (EVA), which is bonded to the front glass and to a rear panel or sheet, which is called a backsheet 108. The backsheet provides the solar module with protection from moisture and other environmental damage, as well as electrical insulation.

Traditionally photovoltaic backsheets are made through a lamination process. Referring also to FIG. 1, a core substrate 110 such as polyethylene terephthalate (PET) film is laminated on both sides with fluoropolymer films 112, 114 such as TEDLAR (a PVF film from DuPont) or KYNAR (a PVDF film from Arkema) using adhesive layers 116. The PET acts as a mechanical support and dielectric insulation layer while the fluoropolymer films provide resistance against weathering.

Prior art laminated backsheets, however, suffer from a number of shortcomings. It is difficult to manufacture laminated structures that will not delaminate after years of exposure to the outdoors. Further, the manufacturing process for prior art laminated backsheets is expensive and time consuming. TEDLAR film is usually laminated to a core PET film one side at a time. Typically, the application of separate primers and adhesives is required before the actual lamination takes place. Also, the laminating adhesive needs time to harden (in some cases requiring several days). Immediately after lamination is completed, the adhesive is still soft and the laminated material is susceptible to damage such as the telescoping of material rolls.

Further, TEDLAR film is a soft material, which is easily marred by metal parts. During module production, handling, and transportation, modules with TEDLAR based backsheets can come in contact with metal parts of machinery which leaves marks or scratches on the backsheets. Some laminated backsheets have one layer of TEDLAR (or KYNAR) and one layer of polyolefin (or ethylene vinyl acetate layer) on a core PET film. Differences in thickness and elasticity of TEDLAR and the polyolefin film can cause such laminated backsheets to curl, which can cause module production issues.

It is also known in the prior art to use coatings, rather than laminated films, to produce backsheets. Typically a fluoropolymer coating is applied on both sides of a core PET film. However, the fluropolymer will usually have poor adhesion to an EVA encapsulant without some special treatment on the fluoro coating surface, such as chemical etching or a corona treatment. These types of surface treatments add cost and complexity to the manufacturing process. It is also know to use a fluoropolymer coating on only one side of a core PET film, with a layer of polyolefin film laminated to the other side of the PET. In this case, a lamination process is still needed, with the resulting problem of delamination. Curl issues also can arise due to the differences in tension induced by the thick layer of polyolefin film on only one side of the substrate.

Traditionally, photovoltaic backsheets are opaque (usually either white or black). However, in some applications—for example when photovoltaic modules are placed on building facades, skylights, or the roofs of a sun rooms—it is desirable for the backsheet of the module to be transparent to let light through. In this case, a transparent PVF or PVDF film is typically used for the backsheet lamination. As used herein, a backsheet will be defined as transparent if it has a total light transmission of greater than 80%.

Prior art transparent laminated backsheets, however, suffer from a number of shortcomings. In a photovoltaic module using a prior art transparent backsheet, the light shines directly through the cell gaps. On a sunny day, the light shining through the cell gaps can be undesirably intense, especially when the sunlight is shining into occupied areas such as a mall or building. It would be more desirable to have transparent backsheet that could diffuse the sun light like the office lighting covers which are patterned plastics.

As such, an improved photovoltaic backsheet would be desirable.

### SUMMARY OF THE INVENTION

A novel backsheet according to preferred embodiments of the present invention is produced using coating formulations and coating processes, which can tailored for surface patterning during module lamination and have lower costs than TEDLA or KYNAR laminated backsheets. In a preferred embodiment, the backsheet is formed by applying distinct coating layers to both sides of a film substrate. The outlier coating layer (on the side exposed to air after the backsheet is laminated to a photovoltaic module) preferably contains a latent cross-linking agent. In some embodiments, the outlier coating layer can be softened during module lamination and can undergo further cross-linking reactions. Further, the backsheet can be patterned, for example by a patterned or textured surface, such as a release blanket, placed on top of the outer coating layer during lamination. The blanket pattern can thus be transferred to the outer coating layer during its softening period in a laminator. During lamination, the backsheet also preferably undergoes a latent cross-linking reaction. After lamination, the further cross-linked outer coating layer will harden and preserve the blanket pattern on the surface of the backsheet. The patterned surface of the outer coating layer will preferably diffuse light passing through the transparent backsheet and through the photovoltaic module.

The foregoing has outlined rather broadly the features and technical advantages of the present invention in order that the detailed description of the invention that follows may be better understood. Additional features and advantages of the invention will be described hereinafter. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The present disclosure may be better understood, and its numerous features and advantages made apparent to those skilled in the art by referencing the accompanying drawings.

FIG. 1 shows a prior art photovoltaic module.

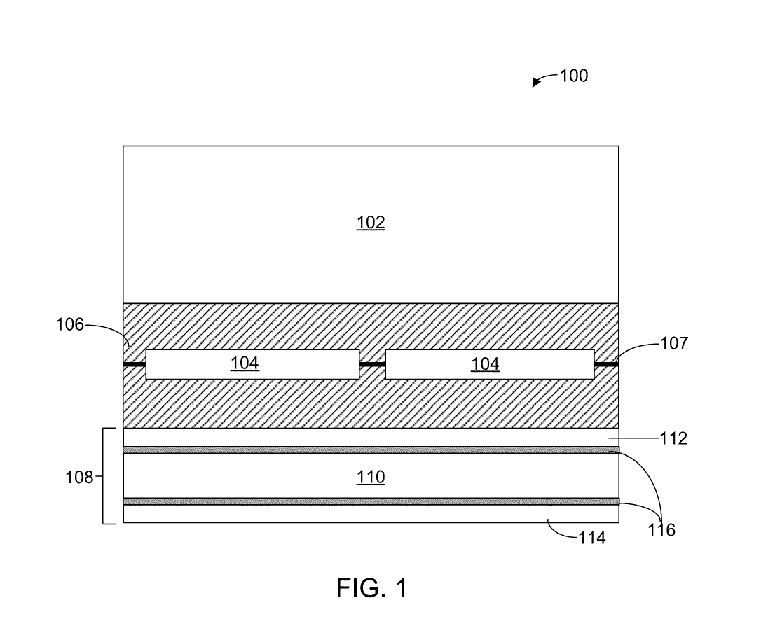

FIGS. 2A-2C show schematically the steps in creating a backsheet for a photovoltaic module according to a preferred embodiment of the present invention.

FIG. 3 is a schematic illustration of a cross-sectional view of photovoltaic module including a backsheet according to a preferred embodiment of the present invention.

FIG. 4 is a flow chart showing the steps in a method of producing a backsheet for a photovoltaic module according to a preferred embodiment of the present invention.

The accompanying drawings are not intended to be drawn to scale. In the drawings, each identical or nearly identical component that is illustrated in various figures is represented by a like numeral. For purposes of clarity, not every component may be labeled in every drawing.

### DESCRIPTION OF THE DRAWINGS

The present invention provides a multilayer photovoltaic backsheet comprising a transparent substrate with same polymeric coatings on both sides of the substrate or a different polymeric coating on either side of the substrate. The use of coatings instead of laminated layers provides for a manufacturing process that is faster, has fewer steps, and is more cost effective. Coatings can be tailored to provide excellent adhesion, without the problems of delamination seen in prior art laminated backsheets.

In a preferred embodiment, the coating layer on the side of the backsheet intended to be exposed to the environment is a transparent and deformable coating applied before module lamination. As used herein, this coating will be referred to as the outer coating. Preferably the outer coating comprises a polymeric resin in solution or dispersion, as described in greater detail below. The inner coating, referring to the coating on the side of the substrate closest to the EVA encapsulant, is preferably transparent and provides excellent adhesion to the substrate and to the EVA encapsulant.

Once the coated backsheet has been prepared, it can be attached to the other elements in a photovoltaic module using a lamination process referred to herein as module lamination, generally by heating the assembled backsheet and the other photovoltaic module elements in the presence of vacuum, pressure, or both. The coating for the outer side of the backsheet substrate can also be tailored to be softened during module lamination. A patterned release film/blanket or other patterned or textured surface can then be pressed against the outer side coating layer during the lamination process. The pattern or texture is thus transferred to the outer side of the backsheet, which will cause light passing through the backsheet to be diffused. A latent cross-linking reaction can further harden the outer side coating layer to increase the outer side coating layer hardness and to improve its durability.

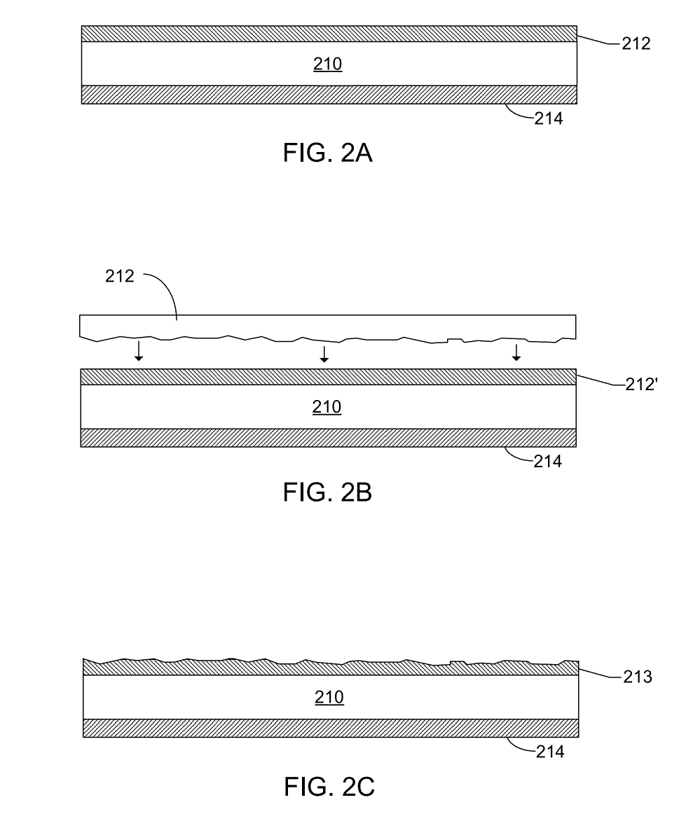

FIGS. 2A-2C show schematically the steps in creating a backsheet for a photovoltaic module according to a preferred embodiment of the present invention. As shown in FIG. 2A, a first inner coating 212 is applied to the inner surface of the substrate on the first side of the substrate, the inner coating preferably including a polymeric resin and a cross-linking agent. A second outer coating 214 is applied to the outer surface of the substrate on the second side of the polymeric film substrate. In one preferred embodiment, the outer coating 214 has the same composition as inner coating 212. In another preferred embodiment, the outer coating 214 has a different composition from inner coating 212, preferably comprising polyester resin and a cross-linking agent. In a preferred embodiment, the polyester resin has an acid value of 1 to 25, more preferably from 1.5 to 5. Acid value is defined as the mass of potassium hydroxide (KOH) in milligrams that is required to neutralize one gram of chemical substance. The acid number is thus a measure of the amount of carboxylic acid groups or other acid groups in a chemical compound or in a mixture of compounds.

The polymeric film substrate can be any suitable transparent polymeric film which provides sufficient electrical insulation and mechanical strength. Suitable transparent polymeric film substrates include PET films such as MYLAR film from DuPont, HOSTAPHAN from Mitsubishi, or SKYROL from SKC. In other preferred embodiments, other polymeric films could be used including polyethylene naphthalate (PEN) film (available from DuPont), polycarbonate film, or a fluoroplastic film.

The outer coating layer according to preferred embodiments of the present invention is a polymeric resin that can deform during module lamination temperature such as from 130° C. to 160° C. In one preferred embodiment, the polymeric resin is a polyester resin. In another preferred embodiment, the polymeric resin is a fluoropolymer resin.

Other additives such as leveling agents, catalysts, UV blocking agents, thermal stabilizers, and/or UV or light stabilizers can also be added to the fluoropolymer coating.

The polymeric can be coated onto the polymeric film substrate using Meyer rod, slot die, gravure or other coating methods known in coating industry. The coating weight of the polymericr coating preferably ranges from 1 g/m² to 100 g/m². More preferably, the coating weight of the fluoropolymer coating ranges from 2 g/m² to 50 g/m².

The inner coating according to embodiments of the present invention shows excellent adhesion to the substrate and to the EVA encapsulant. For example, a suitable polymeric resin for the inner coating could include polyester resin, acrylic resin, or polyurethane. Preferred polymeric resins suitable for use as an inner coating will have functional groups such as hydroxyl, carboxyl and amine groups, which will promote strong adhesion between the inner coating and both the substrate and the EVA encapsulate. In a preferred embodiment, the polymeric resin is selected from high molecular weight polyester resins having both acid and hydroxyl groups.

As with the outer coating, the inner coating can also include the variety of cross-linking agents, or any of the other additives described above.

Preferably, the inner coating materials can be dispersed in water, or even more preferably dissolved in organic solvents. The inner coating solution can be coated on a polymeric substrate using traditional coating methods such as Meyer rod, slot die, gravure, etc. The coating weight of the inner coating preferably ranges from 1 g/m² to 50 g/m². More preferably, the coating weight of the inner coating ranges from 2 to 10 g/m².

In a specific example, an outer coating can be formed from a high molecular weight, linear saturated copolyester resin such as VITEL 2700B and VITEL 2200B (commercially available from Bostik Findley) along with an isocyanate cross-linking agent. Significantly, VITEL 2700B and VITEL 2200B has an acid value of 1-3, which also serves to promote adhesion between the inner coating and both the substrate and the EVA encapsulant. In a preferred embodiment, a polymeric resin for use with embodiments of the present invention will have an acid value of 1 to 20, more preferably from 1.0 to 5.

The outer coating layer (on the side exposed to air after the backsheet is laminated to a photovoltaic module) preferably contains a latent cross-linking agent. Suitable cross-linking agents can be chosen from isocyanate, aziridine, or any other suitable known cross-linking agent.

Once the backsheet has been formed using the method described above, the coated backsheet can be attached to a photovoltaic module using a lamination process, as is known in the industry. In the typical lamination process, the elements of the photovoltaic module—including the front protective substrate, a layer of encapsulant such as EVA, a number of interconnected solar cells, another layer of encapsulant, and the backsheet—are arranged as desired (in a sandwich fashion) and laminated together using the application of heat in the presence of vacuum, pressure, or both.

For example, a vacuum laminator can be used to adhere the backsheet to the photovoltaic module. A vacuum laminator typically comprises a base, on which the photovoltaic module layers are arranged, and a lid or other enclosure that completely covers and surrounds the arranged elements. The enclosed area (including the photovoltaic module elements) can be heated and the atmosphere evacuated. Pressure can be applied to the stacked elements once they are heated, usually by way of an inflatable bladder attached to the top inner surface of the enclosure. When the lid is closed and the bladder inflated, the bladder applies a surface pressure from the top of the enclosure toward the laminator base so that the layers of the photovoltaic module are pressed together. Non-stick release films/blankets may be used to prevent the heated layers from sticking to the base or to the bladder or lid.

In some embodiments, the outer coating layer 212 is softened during module lamination when the backsheet is heated (typically to around 150° C.). As shown in FIGS. 2B-2C, once the outer coating layer has been softened, a patterned or textured surface 216 can be pressed against the softened surface 212′ so that the pattern is transferred to the softened outer coating layer 212′. Preferably this textured surface will be a textured release blanket or even a textured surface on the flexible bladder itself. The resulting patterned outer surface 213 will tend to diffuse or soften light passing through the layer, which results in a more pleasing light quality for the light passing through the transparent backsheet. As would be recognized by a person of skill in the art, a transparent material having a high degree of surface roughness will tend to deflect light passing through that rough surface away from the original incident angle of the light. This is commonly referred to as light diffusion.

Light diffusion can be defined in terms of haze and clarity for the light passing through a transparent material. According to ASTM D 1003, which is hereby incorporated by reference, haze is defined as the percentage of transmitted light that deviates from the incident beam by more than 2.5° on average. Clarity is defined as the percentage of transmitted light that deviates from the incident by more than 0°, but less than 2.5° on average. Materials having a haze value greater than 30% are generally considered to be light diffusing materials.

Preferably, more than 90% of the light passing through the patterned backsheet is diffused, more preferably 100% of the light is diffused. Preferably the patterning results in a backsheet having a haze value that is greater than 30%, greater than 35%, greater than 40%, greater than 50%, or greater than 75%. Further, the patterning preferably results in a backsheet having a clarity of less than 85%, less than 80%, less than 75%, or less than 50%. The patterning also preferably results in greater diffusion of light, as compared to an unpatterned backsheet of the same composition and construction, while the overall percentage of light transmission through the backsheet remains completely or substantially unchanged. In preferred embodiments the percentage of light passing through the patterned backsheet is within 5% of the percentage of light passing through an unpatterned backsheet of the same composition and construction. More preferably, the percentage of light passing through the patterned backsheet is identical to the percentage of light passing through an unpatterned backsheet of the same composition and construction.

Once the outer layer has been softened so that the pattern or texture can be applied, the backsheet also preferably undergoes a latent cross-linking reaction, which is activated by the heat applied during the lamination process. After lamination, the further cross-linked outer coating layer will harden and preserve the blanket pattern on the surface of the backsheet. The latent cross-linking reaction will also serve to increase the outer side coating layer hardness and to improve its durability.

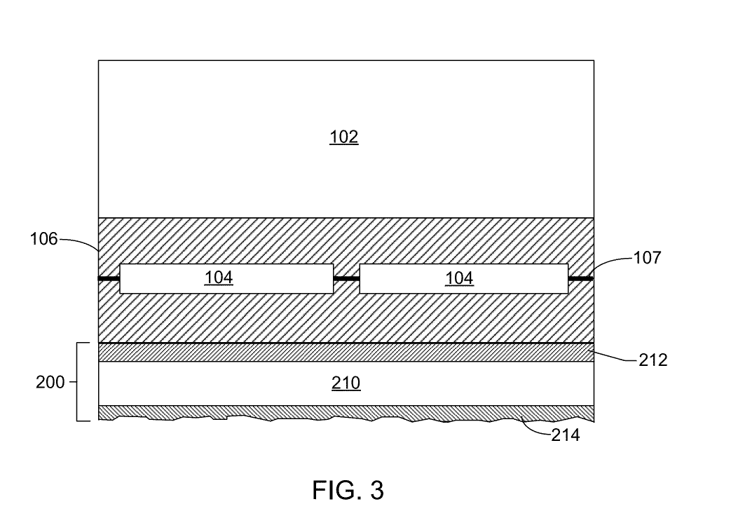

FIG. 3 is a schematic illustration of a cross-sectional view of photovoltaic module including a backsheet according to a preferred embodiment of the present invention. Backsheet 200 comprises a transparent polymeric film substrate 210 having a first side oriented toward the front surface of a photovoltaic module (toward the top glass layer) and a second outer side oriented toward the rear surface of the photovoltaic module (toward the environment on the back-side of the backsheet).

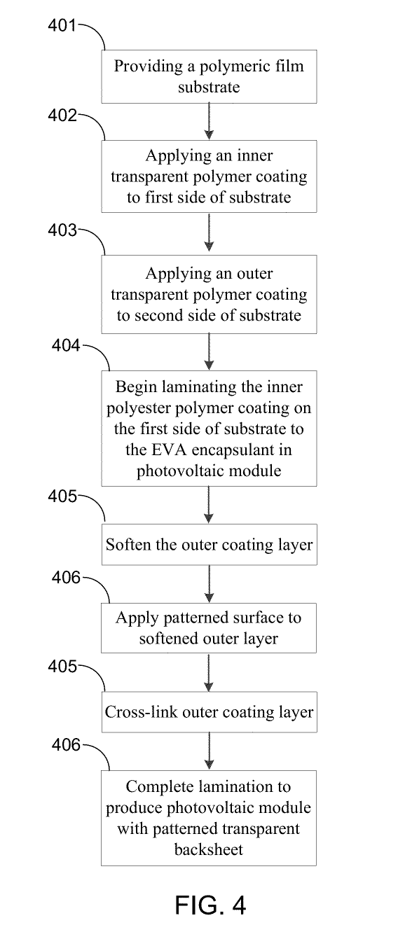

FIG. 4 is a flow chart showing the steps in a method of producing a backsheet for a photovoltaic module according to a preferred embodiment of the present invention. A preferred method of forming a backsheet for a photovoltaic module comprises providing a polymeric film substrate (step 401), such as a PET substrate as described above. When installed into a photovoltaic module, the polymeric film substrate will have a first side oriented toward the front surface of a photovoltaic module (toward the top glass layer) and a second side oriented toward the rear surface of the photovoltaic module (toward the environment on the back-side of the backsheet). Next, in step 402, a first inner coating can be applied to the first side of the polymeric film substrate (the side toward the EVA encapsulant) the first inner coating layer comprising polymeric resin and a cross-linking agent, as discussed above. In step 403, a second coating is applied to the second outer side of the polymeric film substrate, the second coating layer being the same from the first coating layer and comprising polyester resin, and a cross-linking agent. Preferably, the outer coating is formed from a polyester resin having an acid value of 1 to 25, more preferably from 1.5 to 5. The cross-linking agent is preferably a latent cross-linking agent that will not be fully activated until after the backsheet has been patterned and laminated to the other photovoltaic module elements.

In step 404, the process of sealing the backsheet (consisting of the substrate and the two coatings) to the backside of the photovoltaic module by laminating the inner coating to the EVA encapsulant is initiated. In step 405, the outer coating layer is first softened, preferably by the application of heat during the lamination process. Once the outer coating has been softened, in step 406 a patterned surface such as textured release blanket is pressed into the softened outer coating material. This will transfer the pattern from the release blanket (or other textured surface) to the outer coating resulting in a patterned surface on the outer coating layer. In step 406, latent cross-linking agent will cause the outer coating to harden and preserve the blanket pattern on the surface of the backsheet. The latent cross-linking reaction will also serve to increase the outer side coating layer hardness and to improve its durability. In step, 407, the lamination and cross-linking processes are completed.

The samples in the following examples might go though some or all following tests.

Adhesion Test

The sample coating surface was cut with a cross-hatch tool. A tape was applied to the cut area. If coating was pulled off the substrate surface when tape was pulled away, the adhesion was rated as 1; if no coating was pulled off the surface, adhesion was rated at 5. The higher the rating, the better the coating adhesion to the substrate.

Eva Peel Test

The backsheet adhesion to EVA was rated 5 if the backsheet was hard to peel by hand and rated 1 if the backsheet was easy to peel by hand. The higher the rating, the better the backsheet adhesion to EVA. The backsheet adhesion to EVA was also measured by an INSTRON adhesion test if the sample was large enough. For those samples, the backsheet was cut into 1 inch wide sections for the peel test, and actual peel strength is given in pounds/in below.

The invention is further illustrated in the following examples:

### Example 1

An coating solution can be made as follows: 50-60 grams of VITEL V2200B resin (polyester resin from Bostik), 80 to 120 grams of ethyl acetate, 30 to 60 grams of methyl ethyl ketone, 0.5 to 1.2 grams of TINUVIN 292, and 0.5 to 1.2 grams of TINUVIN 384-2 (both types of TINUVIN from Ciba Chemicals) mixed together until VITEL resin is dissolved. Add 5.0 to 8.0 grams of LiofolHaerter UR 7395-22 to the solution to make a suitable inner coating solution.

The coating solution made as described above was coated on the both sides of a PET film with a coating weight of 4 lb/ream. The coating layer had very good adhesion on the PET film (adhesion rating of 5). VITEL V2200B resin is a polyester resin with an acid value of 1-3 mg KOH/g-polymer and an OH value of 3-5 mg KOH/g-polymer.

The backsheet of Example 1 was laminated to a glass with EVA as encapsulant. The backsheet was laminated to an encapsulant layer of EVA to form a structure as follows: outer coating layer/PET/inner coating layer/EVA/Glass. It was found the inventive backsheet of Example 1 had excellent adhesion to EVA.

During lamination, a release blanket with patterns was placed on top of the outer coating. The blanket patterns were thus transferred to the surface of outer coating layer.

### Comparative Example 1

The same backsheet in EXAMPLE 1 was laminated to glass. During the lamination, a smooth release liner film was placed on top of the outer coating. There were no patterns on the surface of the outer coating layer after lamination.

TABLE 1
Test Results.

| | | | % LIGHT | | |
|---|---|---|---|---|---|
| | | | TRANS- | | SURFACE |
| | HAZE | CLARITY | MISSION | VLT | PATTERNS |
| EXAMPLE 1 | 33 | 78 | 86 | 80 | YES |
| COMPARATIVE | 28 | 89 | 86 | 80 | NO |
| EXAMPLE 1 | | | | | |

EXAMPLE 1 and COMPARATIVE EXAMPLE 1 show that a patterned backsheet during module lamination increased module haze and lowered clarity without reducing light transmission rate and visible light transmission (VLT). So the patterned backsheet will scatter light shining through the cell gap area in a transparent PV module for sun roof or other instances that need transparent modules. The increased haze and lowered clarity due to the patterns on the outer surface of backsheet reduces light glare and makes the light more comfortable for eyes.

The present invention has broad applicability and can provide many benefits as described and shown in the examples above. The embodiments will vary greatly depending upon the specific application, and not every embodiment will provide all of the benefits and meet all of the objectives that are achievable by the invention. Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention. After reading the specification, skilled artisans will appreciate that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present). Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

Although the present invention and its advantages have been described in detail, it should be understood that various changes, substitutions and alterations can be made to the embodiments described herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Item 1. A transparent backsheet for a photovoltaic module comprising: a polymeric film substrate for use as a backsheet for a photovoltaic module; a coating on at least one side of the polymeric film substrate, the coating layer comprising transparent polymeric resin and a cross-linking agent, wherein the transparent polymeric resin has an acid value of 1 to 25, said coating layer being a patterned layer; wherein the polymeric film substrate and any applied coatings are transparent to visible light and wherein the backsheet having a patterned coating layer has a haze of greater than 30% and a clarity of less than 85%.

Item 2. A transparent backsheet for a photovoltaic module comprising: a polymeric film substrate for use as a backsheet for a photovoltaic module; a first coating on a first side of the polymeric film substrate, the first coating layer comprising transparent polymeric resin and a cross-linking agent, wherein the transparent polymeric resin has at least one functional acid group and wherein the coating layer is patterned so that light transmitted through the coating is diffused, wherein the backsheet, including the substrate and any applied coating, is transparent.

Item 3. A coated film for use as a transparent backsheet for a photovoltaic module, the coated film comprising: an unlaminated transparent substrate film; a coating applied to at least one side of the substrate film, the coating comprising a transparent polymeric resin having at least one functional acid group and further comprising acrylic resin, polyurethane, and/or fluoropolymer resin; wherein a pattern is applied to the coating, said pattern causing light passing through the transparent substrate to be at least 90% diffused.

Item 4. The coated film of any of the preceding items in which the coating is cross-linked after the pattern is applied.

Item 5. A method of forming a transparent backsheet for a photovoltaic module, the method comprising: providing a transparent polymeric film substrate; applying a coating to at least one side of the polymeric film substrate, the coating layer comprising a transparent polymeric resin and a cross-linking agent, wherein the transparent polymeric resin has an acid value of 1 to 25; applying a pattern to the coating, the pattern resulting in the backsheet having a transmission haze value of at least 30%.

Item 6. The method of any of the preceding items further comprising cross-linking the coating after pattern is applied.

Item 7. The backsheet or film of any of the preceding items having a transparency to visible light of at least 80% visible light transmittance, at least 85% visible light transmittance, or at least 90% visible light transmittance.

Item 8. The backsheet or film of any of the preceding items in which the patterned coating has a haze value of at least 30%, at least 35%, at least 40%, at least 50%, or at least 75%.

Item 9. The backsheet or film of any of the preceding items in which light passing through the backsheet is at least 90% diffused.

Item 10. The backsheet or film of any of the preceding items in which light passing through the backsheet is 100% diffused.

Item 11. The backsheet or film of any of the preceding items in which the substrate film is an unlaminated film.

Item 12. The backsheet or film of any of the preceding items in which the substrate film comprises polyethylene tetrephthalate (PET) film.

Item 13. The backsheet or film of any of the preceding items in which the substrate film comprises polyethylene naphthalate (PEN) film.

Item 14. The backsheet or film of any of the preceding items in which the substrate film comprises polycarbonate or fluoroplastic film.

Item 15. The backsheet or film of any of the preceding items in which the coating comprises a polymeric resin with at least one hydroxyl, carboxyl, or amine functional group.

Item 16. The backsheet or film of any of the preceding items in which the coating comprises polyester resin, acrylic resin and/or polyurethane.

Item 17. The backsheet or film of any of the preceding items in which the coating comprises a high molecular weight polyester resin with at least one acid and one hydroxyl functional group.

Item 18. The backsheet or film of any of the preceding items in which the coating has a coating weight in the range of 1 g/m² to 20 g/m².

Item 19. The backsheet or film of any of the preceding items in which the coating has a coating weight in the range of 2 g/m² to 10 g/m².

Item 20. The backsheet or film of any of the preceding items in which the coating has a coating weight in the range of 10 g/m² to 100 g/m².

Item 21. The backsheet or film of any of the preceding items in which the second coating has a coating weight in the range of 20 g/m² to 50 g/m².

Item 22. The backsheet or film of any of the preceding items in which the coating comprises a fluoropolymer resin.

Item 23. The backsheet or film of any of the preceding items in which the coating comprises a fluoropolymer resin of tetrafluoroethylene (TFE) and ethylene copolymer.

Item 24. The backsheet or film of any of the preceding items in which the coating comprises a fluoropolymer resin of chlorotrifluoroethylene (CTFE) and vinyl ether copolymer.

Item 25. The backsheet or film of any of the preceding items in which the coating further comprises a cross-linking agent selected from isocyanate and/or aziridine.

Item 26. The backsheet or film of any of the preceding items in which the coating further comprises at least one additional additive selected from the group consisting of leveling agents, catalysts, UV blocking agents, UV stabilizers, and combinations thereof.

1. A transparent backsheet for a photovoltaic module comprising:
a polymeric film substrate for use as a backsheet for a photovoltaic module;
a coating on at least one side of the polymeric film substrate, the coating layer comprising transparent polymeric resin and a cross-linking agent, wherein the transparent polymeric resin has an acid value of 1 to 25, said coating layer being a patterned layer;
wherein the polymeric film substrate and any applied coatings are transparent to visible light and wherein the backsheet having a patterned coating layer has a haze of greater than 30% and a clarity of less than 85%.

2. A transparent backsheet for a photovoltaic module comprising:
a polymeric film substrate for use as a backsheet for a photovoltaic module;
a first coating on a first side of the polymeric film substrate, the first coating layer comprising transparent polymeric resin and a cross-linking agent, wherein the transparent polymeric resin has at least one functional acid group and wherein the coating layer is patterned so that light transmitted through the coating is diffused,
wherein the backsheet, including the substrate and any applied coating, is transparent.

3. A coated film for use as a transparent backsheet for a photovoltaic module, the coated film comprising:
an unlaminated transparent substrate film;
a coating applied to at least one side of the substrate film, the coating comprising a transparent polymeric resin having at least one functional acid group and further comprising acrylic resin, polyurethane, and/or fluoropolymer resin;
wherein a pattern is applied to the coating, said pattern causing light passing through the transparent substrate to be at least 90% diffused.

4. The coated film of claim 3 in which the coating is cross-linked after the pattern is applied.

5. The backsheet of claim 1 having a transparency to visible light of at least 80% visible light transmittance.

6. The backsheet of claim 1 in which the patterned coating has a haze value of at least 30%.

7. The backsheet of claim 2 in which light passing through the backsheet is at least 90% diffused.

8. The backsheet of claim 2 in which light passing through the backsheet is 100% diffused.

9. The backsheet of claim 1 in which the substrate film is an unlaminated film.

10. The backsheet of claim 1 in which the substrate film comprises polyethylene tetrephthalate (PET) film.

11. The backsheet or film of claim 1 in which the substrate film comprises polyethylene naphthalate (PEN) film.

12. The backsheet of claim 1 in which the substrate film comprises polycarbonate or fluoroplastic film.

13. The backsheet of claim 1 in which the coating comprises a polymeric resin with at least one hydroxyl, carboxyl, or amine functional group.

14. The backsheet of claim 1 in which the coating comprises polyester resin, acrylic resin and/or polyurethane.

15. The backsheet of claim 1 in which the coating comprises a high molecular weight polyester resin with at least one acid and one hydroxyl functional group.

16. The backsheet of claim 1 in which the coating comprises a fluoropolymer resin.

17. The backsheet of claim 1 in which the coating comprises a fluoropolymer resin of tetrafluoroethylene (TFE) and ethylene copolymer.

18. The backsheet of claim 1 in which the coating comprises a fluoropolymer resin of chlorotrifluoroethylene (CTFE) and vinyl ether copolymer.

19. The backsheet of claim 1 in which the coating further comprises a cross-linking agent selected from isocyanate and/or aziridine.

20. The backsheet of claim 1 in which the coating further comprises at least one additional additive comprising leveling agents, catalysts, UV blocking agents, UV stabilizers, or combinations thereof.
